(19) United States
(12) Patent Application Publication
(10) Pub. No.: US 2003/0205192 A1
(43) Pub. Date: Nov. 6, 2003

(54) Film forming method

(75) Inventors: Yasushi Aiba, Kofu-shi (JP); Takanori Mimura, Kofu-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/460,183

(22) Filed: Jun. 13, 2003

Related U.S. Application Data
(62) Division of application No. 09/646,391, filed on Sep. 18, 2000, now abandoned.
Application No. 09/646,391 is a 371 of international application No. PCT/JP00/00213, filed on Jan. 19, 2000.

(30) Foreign Application Priority Data
Jan. 19, 1999 (JP) 11-011191

(51) Int. Cl. C30B 23/00; C30B 25/00; C30B 28/12; C30B 28/14

(52) U.S. Cl. 117/84

(57) ABSTRACT

A clamp mechanism 35 holding an object W to be processed placed on a susceptor 22 in a processing vessel 16 for film formation which can be vacuumed, includes a ring-shaped clamp ring body 38 contacting a peripheral portion of the object to be processed, and an urging member 40 for urging the clamp ring body downwardly. A contact surface 38A on an inner peripheral side of the clamp ring body is formed as a tapered surface which is inclined at a predetermined angle θ downwardly from the horizontal line outward in the direction of the diameter of the object to be processed. The predetermined angle is set in a range from 2 to 15 degrees, and the amount of overlap between the contact surface and the peripheral edge portion of the object to be processed is set in a range from 0.7 to 3.5 mm. Thus, formation of an unnecessary deposition film in the vicinity of the peripheral portion of the object to be processed and the side surface thereof is properly restricted.

### CROSS REFERENCE TO RELATED APPLICATIONS

The present application is a Division of U.S. patent application Ser. No. 09/646,391, filed on Sep. 18, 2000, and now abandoned.

### BACKGROUND OF THE INVENTION

1. Field of the Invention

The present invention relates to a film forming method for forming a film such as a metal film containing, for example, tungsten, on an object which is to be processed such as a semiconductor wafer or the like.

2. Background of the Invention

Generally, in a process of producing a semiconductor integrated circuit, a thin film is formed by depositing metals or metallic compounds such as w (tungsten), WSi (tungsten silicide), Ti (titanium), TiN (titanium nitride), TiSi (titanium silicide), Cu (copper) and the like to form a wiring pattern on a surface of a semiconductor wafer serving as an object which is to be processed or to fill recess portions between the wirings, etc.

As this kind of metal thin film forming method, three methods, for example, H₂ (hydrogen) reduction, SiH₄ (silane) reduction and SiH₂Cl₂ (dichlorsilane) reduction are known. SiH₂Cl₂ (dichlorsilane) reduction is a method of forming a W film or a WSi film at a high temperature of about 600° C. by using, for example, dichlorsilane as a reducing gas to form a wiring pattern. SiH₄ reduction is also a method of forming a W film or a WSi film at a lower temperature of about 450° C. by using, for example, silane as a reducing gas to form a wiring pattern.

H₂ reduction is a method of depositing a W film at a temperature of about 400 to 430° C. by using, for example, hydrogen as a reducing gas to fill the recess portions between the wirings on a wafer surface.

Any of the above methods uses, for example, WF₆ (tungsten hexafluoride) as a processing gas for film formation.

A general method of forming such a metal thin film will be explained below together with a film forming apparatus, with reference to FIG. 6.

A thin susceptor 4 made of, for example, carbon material or aluminum compound is provided inside a processing vessel 2 molded of, for example, aluminum or the like in a cylindrical shape. Heating means 8 such as halogen lamps are arranged under a transparent window 6 which is formed of quartz and is provided on the bottom of the processing vessel, under the susceptor 4. A semiconductor wafer W as a object to be processed is placed on the susceptor 4. A peripheral portion of the semiconductor wafer W is pressed and fixed on the susceptor 4 by, for example, a substantially ring-shaped clamp ring 10 which is movable move up and down. The clamp ring 10 has very small protrusions 13 whose height H is about 30 to 50 μm on an inner peripheral portion of a lower surface as shown in an expanded view of FIG. 7. About eight protrusions are arranged equally in the peripheral direction (though only one protrusion is shown), and they press the peripheral portion of the wafer as explained above. A shower head portion 12 formed of, for example, aluminum is provided at the upper part of the processing apparatus so as to face the susceptor 4, i.e. to face the semiconductor wafer at a predetermined interval. A great number of gas jet orifices 11 are formed in the lower surface of the head portion in a substantially equally distribution.

When the film is formed, the susceptor is heated by irradiating the heat wave from the heating means 8 onto the susceptor 4 through the transparent window 6 while the semiconductor wafer is pressed and supported on the susceptor 4 by the clamp ring, and the semiconductor wafer W is indirectly heated and maintained at a predetermined temperature, as described above. At the same time, for example, WF₆, H₂, etc. as a processing gas are supplied uniformly onto the wafer surface from the gas jet orifices 11 of the shower head portion 12 provided above the susceptor 4, so that a metal film of W and the like is formed on the wafer surface.

In the above example of the apparatus, a back side gas whose pressure is adjusted flows to the back surface side of the susceptor 4. However, the film forming gas on the processing space side cannot be prevented from flowing to the back surface side of the susceptor 4 through small gaps having a width of about 30 to 50 μm which are formed between the clamp ring 10 and the peripheral portion of the upper surface of the wafer. For this reason, an unnecessary deposition film 15 is slightly formed on the peripheral portion of the wafer W overlapping the clamp ring 10 and also on the side surface of the wafer W, as shown in FIG. 7.

Such an unnecessary deposition film 15 on the side surface of the wafer W has not caused serious problems under the conventional design rules that did not strictly limit the film thickness or the width of the wiring. However, as the design rules became stricter and the element structure became multi-layered, such a deposition film has caused problems, resulting in generation of particles. Specifically, for example, the surfaces such as an interlayer insulation film, a wiring film and the like need to be flattened to prevent a break in the wiring, etc. so that the element can be multi-layered. Generally, CMP (Chemical Mechanical Polishing) and the etch back process are executed as flattening processes after film formation. At this time, only the upper surface of what is called a regular film deposited and attached on the upper surface of the wafer W is mainly ground. Therefore, the unnecessary deposition film 15 on the side surface of the wafer peels off during this processing step or the following steps, causing particles to be formed. The peripheral portion of the wafer does not ground in the CMP processing and thereby residues of the film are generated, resulting in the lowering of the yields.

On the other hand, forming no protrusions on the clamp ring 10, and bringing the lower surface of the clamp ring into surface contact with the peripheral portion of the upper surface of the wafer to prevent the film forming gas from flowing to the back surface side of the wafer can be conceived. In this case, however, the surface of the clamp ring 10 becomes integral with the film deposited on the surface of the wafer and thus the clamp ring 10 cannot is difficult to be peeled off from the wafer W when the wafer is conveyed, and therefore, this measure cannot be taken.

Jpn. Pat. Appln. KOKAI Publication No. 9-115993 (U.S. application Ser. No. 08/729287) proposes a structure of using the inner peripheral side surface of the clamp ring as a tapered surface and bringing the tapered surface into linear contact with the wafer to prevent the film forming gas from flowing to the back surface side of the wafer and the susceptor. This document is attached hereto for reference. However, it is found that the flow of the film forming gas to the side and back surface sides of the wafer largely depends on a slight variation in the shape of the clamp ring. Further, there arises a problem that an allowable quantity of the film deposited on the side surface of the wafer varies in accordance with the kind of processing of the wafer in an after-treatment and the quantity cannot sufficiently be controlled with high accuracy.

### SUMMARY OF THE INVENTION

The object of the present invention is to provide a film forming method capable of properly restricting the formation of an unnecessary deposition film in the vicinity of a peripheral portion and a side surface of a object to be processed, and thus capable of forming a thin film on the object to be processed so as to restrict the generation of particles to the minimum or prevent the generation thereof even if the formed film is subjected to flattening.

After diligently studying the deposition of the film in the vicinity of the side surface of the semiconductor wafer, the present inventors have accomplished the present invention by achieving the knowledge that the deposition of the film on the outer side surface of the wafer largely depends on a correlation between the amount of overlap of the clamp ring body and the upper peripheral portion of the semiconductor wafer, and the tapering angle of the wafer contact portion of the clamp ring body.

A film forming method according to a first aspect of the present invention comprises forming a film on a wafer using a processing vessel, a gas supply mechanism for supplying a processing gas for film formation into the processing vessel, a susceptor provided in the processing vessel, on which a object to be processed is placed, a clamp mechanism for supporting the object to be processed on the susceptor while clamping the object to be processed with the susceptor, and a heating source for heating the object to be processed on the susceptor, to form a film having a predetermined thickness on the object to be processed, by a processing gas. The clamp support mechanism comprises a ring-shaped clamp body having an inner peripheral contact surface, which defines an opening having an inner diameter smaller than an outer diameter of the object to be processed so as to overlap, with an outer peripheral portion of the object to be processed along an entire periphery thereof a length L, the peripheral contact surface being inclined downwardly at a predetermined angle θ, outwardly in the direction of the diameter of the object to be processed. The clamp body has an outer diameter larger than the outer diameter of the object to be processed. The clamp support mechanism includes a drive mechanism for pressing the ring-shaped member toward the object to be processed and making the inner peripheral contact surface abut on an outer peripheral edge of the object to be processed to prevent the processing gas from flowing outside from the outer periphery of the object to be processed; and flattening the film using an etch back process.

The length of overlap L and the angle θ of the inner peripheral contact surface of the ring-shaped member are set such that the film formed on the object to be processed has a thickness of at least 90% of the predetermined thickness, in a central region 0.4 mm remote from the outer peripheral edge of the object to be processed, and that the film cannot be formed on an outer peripheral portion of a wafer or a back surface thereof.

Thus, the deposition of the unnecessary film on the outer peripheral surface of the object to be 15 processed and in the vicinity of outer peripheral surface can be properly restricted.

### BRIEF DESCRIPTION OF THE DRAWINGS

FIG. 1 is a schematic view showing a structure of a film forming apparatus according to the present 20 invention;

FIG. 2 is an enlarged sectional view showing a relationship between a clamp ring main body of a clamp mechanism in the apparatus of FIG. 1 and a semiconductor wafer;

FIG. 3 is an enlarged side view showing a distal end portion of the clamp ring main body;

FIG. 4 is a diagram showing a relationship between an outer periphery of the semiconductor wafer, i.e. a distance from an edge (an overlap length), and the film thickness rate, to form a film suitable for the etch back process;

FIG. 5 is a diagram showing a relationship between an outer periphery of the semiconductor wafer, i.e. the distance from an edge (the overlap length), and the film thickness rate, to form a film suitable for the CMP process;

FIG. 6 is a view showing a general film forming apparatus; and

FIG. 7 is an enlarged view showing a clamp ring used in the film forming apparatus shown in FIG. 6.

### DESCRIPTION OF THE PREFERRED EMBODIMENTS

A method including a film forming apparatus according to an embodiment of the present invention will be explained in detail with reference to the attached drawings.

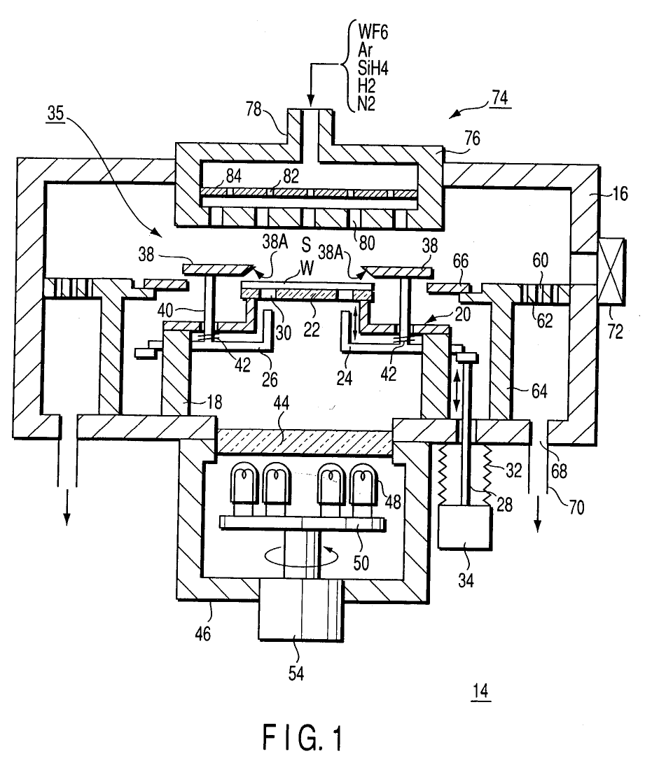

A film forming apparatus 14 has a processing vessel 16 molded of a metal such as aluminum in a shape of a cylinder or a casing, as shown in FIG. 1. A cylinder-shaped reflector 18 standing up from a bottom portion of the processing vessel is provided inside the processing vessel 16. Horizontal proximal end portions of holding members 20 each having, for example, an L-shaped section, are provided on the top surface of the reflector 18. A susceptor 22 on which a semiconductor wafer W serving as an object to be processed is placed is horizontally provided on a vertical distal end portions of the holding members. The reflector 18 and the holding member 20 are formed of an object of heat-ray transmittance such as quartz. The susceptor 22 is formed of an aluminum compound such as a carbon material, AlN, etc. having a thickness of about 1 mm.

A plurality of lifter pins 24, for example, three lifter pins (only two ones shown in the present embodiment) are fixed the forward ends of support members 26 to stand upward, under the susceptor 22. Proximal ends of the support members extend outside of the reflector 18 through vertical slits formed in the reflector. These support members 26 are connected to one another by an annular connection member so as to vertically move together. An extending end of one of the support members is attached to an upper end of a push rod 28 vertically extending through the bottom portion of the processing vessel. Thus, the three lifter pins 24 may he inserted into lifter pin holes 30 provided through the susceptor 22, via the support members 26, so that the wafer W can be lifted up from the susceptor or placed on the susceptor.

A lower end of the push rod 28 is connected to an actuator 34 through a bellows 32, which can be extended to maintain an air-tight condition inside the processing vessel 16. A clamp mechanism 35 for holding the peripheral portion of the wafer W and fixing it on the susceptor 22 side is provided at the peripheral portion of the susceptor 22. The clamp mechanism 35 comprises a ring-shaped clamp ring body 38, which is brought into linear contact with the upper surface near the peripheral side surface of the semiconductor wafer W, i.e. the peripheral portion thereof along the entire periphery, i.e. which presses and fixes it, and a coil spring 42 serving as urging means for urging the clamp ring body downwardly. Specifically, the clamp ring body 38 has a circular or wafer-shaped opening, which is arranged coaxial with the susceptor 22, i.e. the semiconductor wafer W placed on the susceptor and which has a slightly smaller inner diameter than the outer diameter of the semiconductor wafer. Consequently, when the semiconductor wafer W is pressed by the clamp ring body 38, the semiconductor wafer except the peripheral portion is exposed from the opening of the ring body 38. The exposed portion is a film formation region where a film having a predetermined thickness is formed. The outer diameter of the ring body 38 is set arbitrarily, but set to be at least larger than the outer diameter of the wafer. The ring body 38 is formed of a material which has a resistance to heat and which is hardly corroded by the processing gas, for example, a ceramic material. As for this ceramic material, for example, AlN, or AlN whose surface is coated with Al₂O₃ is preferably used.

The inner peripheral surface defining the opening, of the clamp ring body 38, is a tapered surface as described later, which forms a surface 38A contacting 5 the wafer. The clamp ring body 38 is supported on top ends of three support rods 40 (two of which are shown) inserted into three through holes formed in the holding members 20, so as to penetrate the holding members. Lower ends of the support rods are supported respectively by the support members 26. As a result, the clamp ring body can be moved up and down, integrally with the lifter pins 24, by the upward and downward movements of the support members 26. The compression coil spring 42 is provided between the holding member 20 and the support member 26 so as to surround the support rod 40. The coil springs always urge downwardly the clamp ring body 38, etc. When the clamp ring body 38 is moved down and stopped to abut on the semiconductor wafer W, the coil springs urge the ring body downwardly and thereby make the abutting on the semiconductor wafer certain, i.e. make the clamping of the wafer incorporated with the susceptor certain. The lifter pins 24, the support members 26 and the holding members 20 are also formed of a heat-ray 25 transmitting member such as quartz.

A circular opening is formed immediately under the susceptor 22, i.e. the bottom portion of the processing vessel surrounded by the cylinder-shaped reflector 18. The opening is closed air-tightly by a transmitting window 44 formed of a heat-ray transmitting member such as quartz. A casing-shaped heating chamber 46 is provided to surround the transmitting window 44, under this transmitting window. A plurality of heating lamps 48 serving as heating means are attached to a rotary susceptor 50 serving as a reflector, inside the heating chamber 46. The rotary susceptor 50 is rotated in a direction represented by an arrow, by a rotary motor 54 provided on the bottom portion of the heating chamber 46, through a rotary shaft. Therefore, the heat rays emitted from the rotated heating lamps 48 uniformly irradiate the lower surface of the susceptor 22 through the transmitting window 44 and can thereby heat it. Resistance heaters may be provided as the heating means in place of the heating lamps.

Ring-shaped current plate 62 having a plurality of current apertures 60 are supported by a support column 64 formed vertically in an annular shape, at the outer peripheral side of the susceptor 22, inside the processing vessel 16. A ring-shaped quartz-made attachment 66 for contacting the outer peripheral portion clamp ring body 38 to prevent the gas from flowing below this when the clamp ring body 38 is at the clamping position is provided on the inner peripheral side of the current plate 62. Exhaust ports 68 are provided at the bottom portion of the processing vessel under the current plate 62. Exhaust paths 70 connected to a vacuum pump (not shown) are also connected to the exhaust ports 68 to maintain a predetermined degree of vacuum inside the processing vessel 16.

A gate valve 72, which is opened/closed when the wafer is brought in/out, is provided on the side wall of the processing vessel 16.

A shower head portion 74 serving as gas supply means for introducing a processing gas into the processing vessel 16 is provided on a processing vessel ceiling portion which faces the susceptor 22, so as to define a processing space S while having a predetermined interval with the semiconductor wafer W. Specifically, the shower head portion 74 formed in a circular-shape casing of a metal such as aluminum and has a head body 76. A gas intake port 78 is provided on a ceiling portion of the head body. Gas sources (not shown) for gases necessary for a film forming process, for example, WF₆, Ar, SiH₄, H₂, N₂, etc., are connected to the gas intake port 78 through a gas path so as to control the flow amount. A number of gas injection ports 80 for emitting the gas supplied in he head body 76 into the processing space S are arranged on the substantially entire surface of the lower wall of the head body 76, so that the gas is emitted to the wafer surface.

A diffusion plate 84 having a number of gas dispersion apertures 82 is arranged within the head body 76 to uniformly supply the gas onto the wafer surface.

A gas port for supplying purge gas to allow it to flow toward the lower surface side of the susceptor 22, i.e. upwardly along the sides of the semiconductor wafer, is provided in the bottom wall of the processing vessel though not shown.

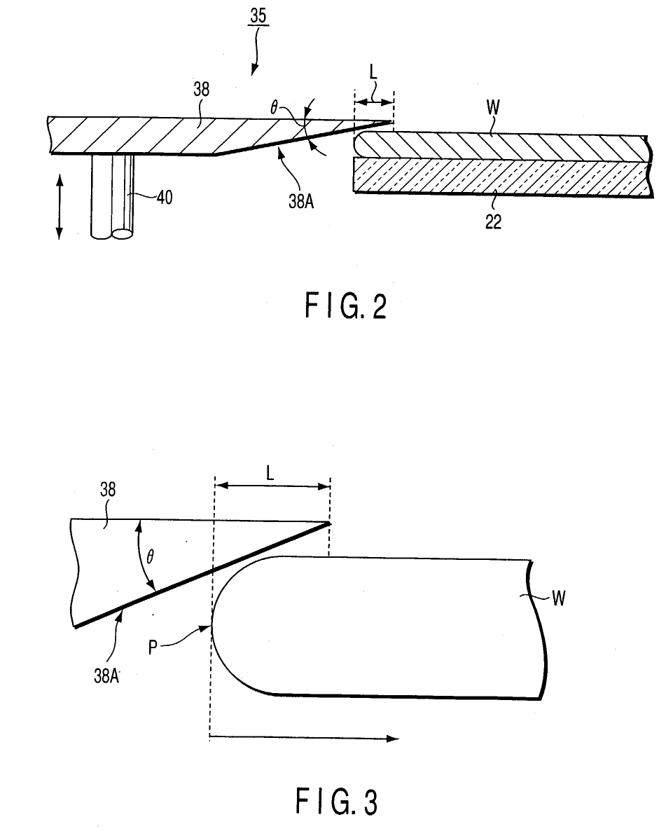

Next, the clamp ring body 38 of the clamp mechanism 35 will be explained in detail with reference to FIGS. 2 and 3. The contact surface 38A of the inner peripheral surface of the clamp ring body 38 is formed as a tapered surface inclined at a predetermined angle θ downwardly from the horizontal line outward in the direction of the diameter of the semiconductor wafer W, as described above. Therefore, the contact surface 38A can press the wafer W while being brought into linear contact with the peripheral edge portion of the upper surface of the wafer W so as to form a ring along the entire periphery. Thus the gas tight of this contact portion is remarkably improved. The side surface of the peripheral portion of the wafer W is formed in a shape of a curve or an arc.

The angle θ of the contact surface 38A of the clamp ring body 38 is set to be preferably in a range from 2 to 15 degrees, in order to properly restrict an unnecessary deposition film on the side surface of the wafer. The amount of overlap (length) L between the contact surface 38A and the peripheral portion of the wafer W is set to be preferably in a range from 0.7 to 3.5 mm. The thickness of the clamp ring body 38 substantially ranges from 1.0 to 1.5 mm.

The angle θ and the amount of overlap L are set at more proper values in accordance with the provided processing in the after step of the semiconductor wafer W. For example, if the semiconductor wafer W is to be subjected to the CMP processing after the film formation executed by using the present apparatus, the angle θ is in a range of 2 to 15 degrees and the amount of overlap L is in a range of 1.5 to 3.5 mm. Preferably, the angle θ is 5 degrees and the amount of overlap L is 2.0 mm. If the semiconductor wafer W is to be subjected to the etch back process after the film formation, the angle θ is in a range of 2 to 15 degrees and the amount of overlap L is in a range of 0.7 to 2.35 mm. Preferably, the angle θ is 10 degrees and the amount of overlap L is 1 mm.

Next, the operations of the present embodiment constituted as described above, in a case of forming a metal film of, for example, tungsten on the surface of the semiconductor wafer, will be explained.

First, the gate valve 72 provided on the side wall of the processing vessel 16 is opened, the wafer W is conveyed over the susceptor 22 inside the processing vessel 16 by a conveyance arm (not shown), and the wafer W is handed over the lifter pins 24 by pushing up the lifter pins 24. Then, the lifter pins 24 are moved down by lowering the push rod 28, the wafer W is placed on the susceptor 22, and the peripheral portion of the wafer W is pressed and fixed by the clamp ring body 38 of the clamp mechanism 35 by further moving down the push rod 28. At this time, the tapered contact surface 38A of the clamp ring body 38 is brought into linear contact with the peripheral edge portion of the upper surface of the wafer, so as to make good air-tight condition. Additionally, the peripheral edge portion of the wafer W is pressed downwardly and the overall wafer is fixed on the susceptor 22 by the elastic force of the coil springs 42 serving as the urging means.

Next, WF₆, SiH₄, H₂, etc. are supplied at a predetermined amount, as processing gases, from the processing gas sources (not shown) to the shower head portion 74. The gases are mixed and supplied substantially uniformly from the gas injection ports 80 in the lower surface of the head body 76 into the processing vessel 16. Simultaneously, the interior of the processing vessel 16 is set to be a predetermined degree of vacuum, for example, a value in a range from 200 Pa to 11000 Pa by sucking and exhausting the inner atmosphere from the exhaust ports 68, and the heating lamps 48 positioned under the susceptor 22 are driven while rotated so as to emit the thermal energy. The emitted heat wave passes through the transmitting window 44, irradiates the back surface of the susceptor 22 and heats it. The susceptor 22 is rapidly heated since it is very thin, i.e. about 1 mm as described above. Therefore, the wafer W placed thereon can be rapidly heated at a predetermined temperature. The supplied mixed gases make a predetermined chemical reaction, for example, the tungsten film is deposited and formed over the entire surface of the upper surface of the wafer.

When the film forming process is thus being executed, most parts of the processing gases introduced into the processing space S decompose, diffuse to the surroundings after making a film forming reaction, flow downwardly through current apertures 60 of the current plate 62 provided around the susceptor 22 and discharged outside the processing vessel 16 through the exhaust ports 68. On the other hand, the contact portion between the peripheral edge portion of the upper surface of the wafer and the contact surface 38A of the clamp ring body 38 is not completely sealed, and therefore, part of the processing gases comes close to flowing to the sides of the side surface and the back surface of the wafer W through very small gaps formed at the contact portion.

In the present invention, however, the angle of inclination θ of he contact surface 38A of the clamp ring body 38 and the amount of overlap L between the to end and the peripheral portion of the wafer are set to be in an optimum range, i.e. set to be the values such that the film formed on the object to be processed has a thickness of at least 90% of the predetermined thickness in the central region 0.4 mm remote from the outer periphery of the object to be processed and that the film is not formed on he outer peripheral portion or the back surface of the wafer. Therefore, the processing gases intruding to the sides of the side surface and the back surface of the wafer can be restricted and an unnecessary film deposited on this portion can be properly controlled to be prevented.

The angle θ of the contact surface 38A of the clamp ring body, i.e. the ring-shaped clamp body 38, and the amount of overlap L (length) have been variously varied to check the conditions in the thickness of the formed film and review the relationship between the film flattening, i.e. CMP (Chemical Mechanical Polishing) executed after the film formation and the etch back process. Typical examples of them will be explained here.

Table 1 shows the film thickness to the distance from the outer periphery of the wafer and the film thickness rate when a tungsten film having a thickness of 5000 Å is formed where the amount of overlap L is set at 1 mm and the angle θ is set at 5 and 10 degrees.

TABLE 1

| Distance from | | | | | | | | | |
|---|---|---|---|---|---|---|---|---|---|
| periphery | | 0.24 | 0.32 | 0.46 | 0.7 | 1.0 | 1.5 | 2.0 | 3.0 |
| θ= 5° | Rate | 0 | 1 | 10 | 92 | 99 | 100 | 100 | 100 |
| | Thick- | 0 | 50 | 750 | 4700 | 4950 | 5000 | 5000 | 5000 |
| | ness | | | | | | | | |
| θ= | Rate | 0 | 3 | 16 | 96 | 99 | 100 | 100 | 100 |
| 10° | Thick- | | | | | | | | |
| | ness | 0 | 150 | 800 | 4900 | 5000 | 5000 | 5000 | 5000 |

On this susceptor, the upper stage represents the film thickness rate (%) and the lower stage represents the film thickness (Å).

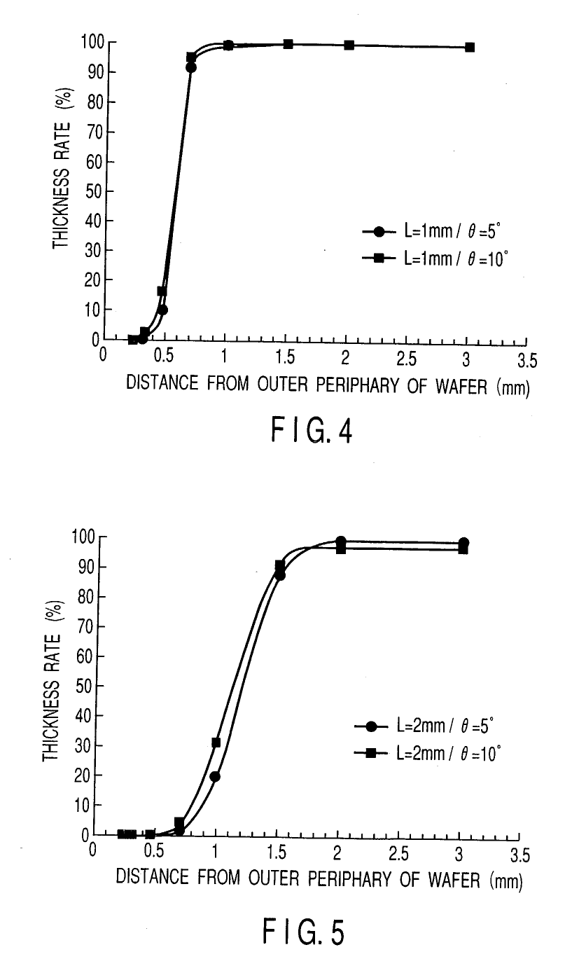

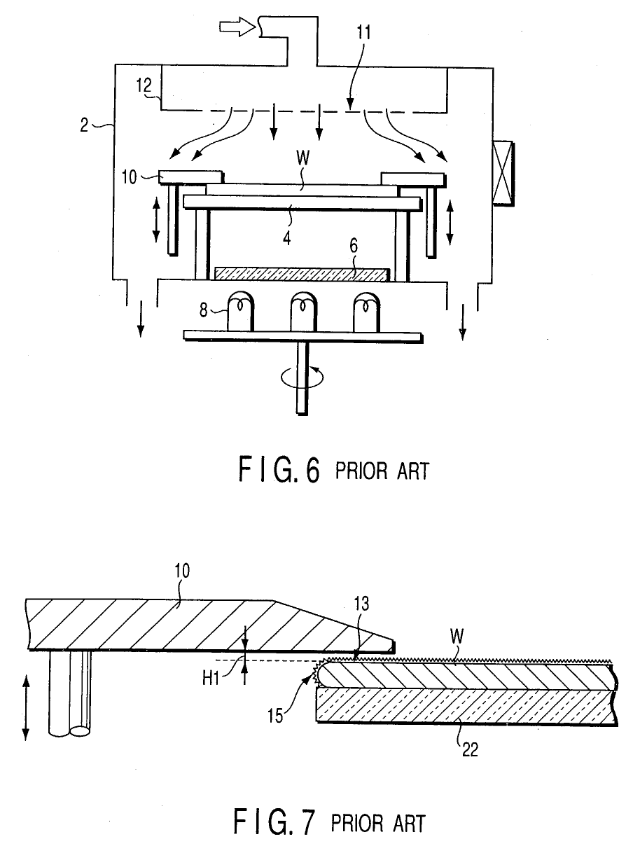

FIG. 4 is a diagram showing the variation of the film thickness rate to the distance by representing the film thickness rate (%) in the vertical axis and the distance from the outer periphery of the wafer to the center thereof in the horizontal axis, on the basis of the data illustrated on Table 1. In this figure, a black circle represents the value where the angle θ is 5 degrees and a black square represents the value where the angle θ is 10 degrees.

According to the inventors' experiments, the film condition required in the etch back process, is that the film thickness rate should be 90% or higher in the region which is remote from the outer periphery of the wafer in shorter than 0.4 mm and the film should not be formed on the outer peripheral portion or the back surface of the wafer. If the film is formed on the outer peripheral portion or the back surface of the wafer, the peeling of the film will result in the generation of the particles. The above measurement results satisfy this condition, and it is therefore clarified that no problems will occur in the following etch back process by forming the film by use of the clamp ring in which the distance L is 1 mm and the angle θ is 5 degrees or 10 degrees.

According to the inventors' experiments, it is understood that if the distance of overlap L is in a range from 0.7 to 2.35 mm and the angle θ is in a range from 2 to 15 degrees, no problems occur in the etch back process.

Table 2 shows the film thickness to the distance from the outer periphery of the wafer and the film thickness rate when a tungsten film having a thickness of 5000 Å is formed where the amount of overlap L is set at 2 mm and the angle θ is set at 5 and 10 degrees.

TABLE 2

Distance from

| periphery | | 0.24 | 0.32 | 0.46 | 0.7 | 1.0 | 1.5 | 2.0 | 3.0 |
|---|---|---|---|---|---|---|---|---|---|
| 0 = | Rate | 0 | 0 | 0 | 1.6 | 20 | 88 | 100 | 100 |
| 5° | Thick- | 0 | 0 | 0 | 80 | 100 | 4400 | 5000 | 5000 |
| 0 = | ness | | | | | | | | |
| 10° | Rate | 0 | 0 | 0 | 4 | 32 | 92 | 98 | 98 |
| | Thick- | 0 | 0 | 200 | 1600 | 4600 | 4900 | 4900 | |
| | ness | | | | | | | | |

FIG. 5 is a diagram showing the variation of the film thickness rate to the distance by representing the film thickness rate (%) in the vertical axis and the distance from the outer periphery of the wafer to the center thereof in the horizontal axis, on the basis of the data illustrated on Table 2. In the figure, a black circle represents the value where the angle θ is 5 degrees and a black square represents the value where the angle θ is 10 degrees.

According to the inventors' experiments, the film condition required in the CMP, is that the film thickness rate should be 90% or higher in the region which is remote from the outer periphery of the wafer in shorter than 2.0 mm and the film should not be formed on the level portion outward in 0.5 mm from the outer peripheral portion of the wafer or the back surface of the wafer. If the film is formed on the level portion outward in 0.5 mm from the outer peripheral portion of the wafer or the back surface of the wafer, the peeling of the film will result in the generation of the particles, or the outer peripheral portion of the wafer is not polished in the CMP, which will result in the generation of the residues of the film. The above measurement results satisfy this condition, and it is therefore clarified that no problems will occur in the following CMP by forming the film by use of the clamp ring in which the distance of overlap L is 2 mm and the angle θ is 5 degrees or 10 degrees.

According to the inventors' experiments, it is understood that if the distance of overlap L is in a range from 1.5 to 3.5 mm and the angle θ is in a range from 2 to 15 degrees, no problems occur in the CMP.

The clamp mechanism of the film forming apparatus of the present invention can be applied to the wafers of all the sizes, for example, 6 inches, 8 inches, 12 inches, etc., irrespective of the wafer size. Additionally, the kind of the formed film is not limited to a tungsten film. The film forming apparatus of the present invention can be also applied to the formation of the other metal films such as a copper film, and insulation films of an SiO₂ film, an SiN film, etc.

Further, the object to be processed is not limited to the semiconductor wafer, and the film forming apparatus of the present invention can be also applied to an LCD substrate, a glass substrate, etc.

### Industrial Applicability

As explained above, the following excellent advantage can be achieved from the film forming apparatus of the present invention.

The angle of inclination of the contact surface of the clamp ring body and the amount of overlap with the object to be processed are set in an optimum range, and therefore, formation of an unnecessary deposition film in the vicinity of the peripheral portion of the object to be processed and the side surface thereof can be properly restricted.

Particularly, if the angle of inclination is set in a range from 2 to 15 degrees and the amount of overlap is set in a range from 1.5 to 3.5 mm, the clamp mechanism suitable for the CMP can be accomplished.

Further, if the angle of inclination is set in a range from 3 to 15 degrees and the amount of overlap is set in a range from 0.7 to 2.35 mm, the clamp mechanism suitable for the etch back process can be accomplished.

1. A method comprising the steps of:
forming a film on a wafer using a processing vessel; a gas supply mechanism for supplying a processing gas for film formation into the processing vessel; a susceptor provided in the processing vessel, on which an object to be processed may be placed; a clamp support mechanism for supporting the object to be processed on said susceptor while clamping the object to be processed with said susceptor; and a heating source for heating the object to be processed on said susceptor, to form a film having a desired thickness on the object to be processed, by the processing gas, said clamp support mechanism comprising a ring-shaped clamp body having an inner peripheral contact surface, which defines an opening having an inner diameter smaller than an outer diameter of the object to be processed so as to overlap with an outer peripheral portion of the object to be processed along an entire periphery thereof by a length L, the peripheral contact surface being inclined downwardly at a predetermined angle θ, and outwardly in the direction of the diameter of the object to be processed, the clamp body having an outer diameter larger than the outer diameter of the object to be processed, the clamp support mechanism including a drive mechanism for pressing said ring-shaped member toward the object to be processed and making said inner peripheral contact surface abut on an outer peripheral edge of the object to be processed, wherein the length L and the angle θ range from 0.7 to 2.35 mm and from 2 to 15 degrees, respectively, such that the film formed on the object to be processed has a thickness of at least 90% of said desired thickness, in a central region 0.4 mm remote from the outer peripheral edge of the object to be processed, and that the film is not formed on a back surface of the object; and
flattening the film on the wafer using an etch back process.
